(19) United States
(12) Patent Application Publication
(10) Pub. No.: US 2023/0333475 A1
(43) Pub. Date: Oct. 19, 2023

(54) COMPOSITE MATERIAL COMPRISING A RELEASE MATERIAL AND A THERMOPOLYMER MATERIAL, AND USES THEREOF

(71) Applicant: Terecircuits Corporation, Mountain View, CA (US)

(72) Inventors: Jayna Sheats, Palo Alto, CA (US); Matthew Robinson, Orinda, CA (US); Dillon M. Love, Mountain View, CA (US)

(21) Appl. No.: 18/300,002

(22) Filed: Apr. 13, 2023

Related U.S. Application Data
(60) Provisional application No. 63/362,988, filed on Apr. 14, 2022.

(51) Int. Cl. G03F 7/11; G03F 7/004

(52) U.S. Cl. CPC G03F 7/11; G03F 7/0045

(57) ABSTRACT

A composite material comprising a release material and a thermopolymer material, and its uses thereof, is described. The composite material may provide improved adhesiveness to components disposed thereon. The composite material may receive a plurality of components from an initial substrate, and may transfer the plurality of components once the initial substrate is removed.

### INCORPORATION BY REFERENCE TO ANY PRIORITY APPLICATIONS

Any and all applications for which a foreign or domestic priority claim is identified in the Application Data Sheet or PCT Request as filed with the present application are hereby incorporated by reference under 37 CFR 1.57, and Rules 4.18 and 20.6, including U.S. Provisional Application No. 63/362,988, filed Apr. 14, 2022.

### BACKGROUND

### Field

This disclosure relates to release layers used to releasably transfer components from one surface to another during manufacturing of microelectronic devices.

### Description of the Related Art

Prior to a Light-Induced Forward Transfer (“LIFT”) process described in U.S. Pat. Nos. 6,946,178 and 7,141,348, whereby a donor plate coated with a release layer with components attached thereto provides selective transfer capability for placement of the components onto a product substrate (e.g., a display backplane or printed circuit board), a pre-LIFT process may be utilized to transfer components from a source substrate to such a donor plate coated with a release layer. This pre-LIFT process typically involves a parallel (i.e., non-selective) transfer of all the components from the source substrate to the donor plate with no change in orientation or relative position. In order to accomplish the pre-LIFT process, the adhesion of the components to the release layer should be greater than it is to the adhesive material holding the components to the source substrate. The material bonding the components to the source substrate may be organic or inorganic (e.g., a wax) with strong adhesive properties.

As such, improvements in this process, and specifically increased adhesivity of the release layer to the components to be transferred, may be beneficial.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the invention herein disclosed. These and other embodiments will become readily apparent to those skilled in the art from the following detailed description of the preferred embodiments having reference to the attached figures, the invention not being limited to any particular preferred embodiment(s) disclosed.

In one aspect, a composite material is disclosed. The composite material includes: a release material comprising a photoactive polymer; and a thermopolymer material comprising a thermopolymer compound.

In some embodiments, the thermopolymer compound is a selected from the group consisting of a thermoplastic, a thermoset, a copolymer thereof, and a combination thereof. In some embodiments, the thermopolymer material has a glass transition temperature of about 50° C.-150° C. In some embodiments, the release material further comprises a photoacid generator (PAG).

In some embodiments, the composite material is a film. In some embodiments, the film comprises a thickness of about 1 um-100 um. In some embodiments, the film is a single layer. In some embodiments, the film comprises a plurality of layers. In some embodiments, a first layer comprises the release material and a second layer comprises the thermopolymer material.

In some embodiments, a carrier assembly is disclosed, including: a carrier substrate; and the composite material disposed over the carrier substrate. In some embodiments, the carrier assembly further includes a component disposed over and in contact with the composite material.

In some embodiments, wafer assembly is disclosed, including: a wafer substrate; a plurality of components disposed over the wafer substrate; and the composite material disposed over and in contact with the plurality of components. In some embodiments, the wafer assembly further includes a carrier substrate disposed over the composite material.

In another aspect, a process is disclosed. The process includes: contacting a composite material layer disposed over a carrier substrate to a plurality of components disposed over an initial substrate, wherein the composite material layer comprises a release material and a thermopolymer material; and removing the initial substrate to result in a plurality of components adhered to the composite material layer.

In some embodiments, the initial substrate is a donor plate. In some embodiments, the donor plate comprises an adhesive layer positioned between the donor plate and the plurality of components. In some embodiments, the initial substrate is a wafer. In some embodiments, the removal of the wafer comprises thinning the wafer.

In some embodiments, the process further includes degrading the composite material layer. In some embodiments, degrading the composite material releases the plurality of components and transfers the plurality of components to a receiving substrate. In some embodiments, the receiving substrate is selected from the group consisting of a donor plate, a package substrate, a backplane, and combinations thereof. In some embodiments, the composite material layer comprises a first layer comprising the release material and a second layer comprising the thermopolymer material, and wherein degrading the composite material degrades the second layer thereby bonding the plurality of components to the first layer. In some embodiments, degrading the composite material comprises exposing the composite material to a process selected from the group consisting of irradiating, heating, a LIFT process, an LLO process, and combinations thereof. In some embodiments, the process further includes contacting the plurality of components adhered to the composite material layer to a handle adhesive disposed over a handle substrate, and transferring the plurality of components away from the composite material to the handle adhesive.

### BRIEF DESCRIPTION OF THE DRAWINGS

FIG. 1 depicts a process of transferring components utilizing a composite material, according to some embodiments.

FIG. 2 depicts a process of dicing a wafer into individual die components and placing them onto a stretchable film utilizing a composite material, according to some embodiments.

FIG. 3 depicts a process of transferring components from a source substrate to a carrier substrate by utilizing a bilayer composite material, according to some embodiments.

These and other embodiments are provided throughout the Application and in greater detail below.

### DETAILED DESCRIPTION

Although certain embodiments and examples are described below, those of skill in the art will appreciate that the invention extends beyond the specifically disclosed embodiments and/or uses and obvious modifications and equivalents thereof. Thus, it is intended that the scope of the invention herein disclosed should not be limited by any particular embodiments described below.

A composite material is utilized for transferring components from one substrate (e.g., wafer) to another (e.g., a donor plate), and acts as an adhesive and/or release layer. The composite material includes a release material (e.g., Terefilm®) and a thermopolymer material (e.g., wax). In some embodiments, a transfer adhesive (e.g., a transfer adhesive used on dicing tapes) may be used in addition to or instead of a thermopolymer material. In some embodiments, the composite material comprises a photoacid generator (PAG). In some embodiments, the composite material does not include a photoacid generator. In some embodiments, the combination of the thermopolymer material and the release material may allow for a composite material that is softer (i.e., lower hardness) and/or can be formed into a thicker film relative to a release material alone.

In some embodiments, the composite material is formed into film with a thickness of, of about, of at least, or of at least about, 0.5 um, 0.75 um, 1 um, 5 um, 10 um, 15 um, 20 um, 25 um, 30 um, 40 um, 50 um, 75 um, 100 um, 125 um, 150 um or 200 um, or any range of values therebetween. In some embodiments, the composite material comprises a thermopolymer material layer with a thickness of, of about, of at least, or of at least about, 0.5 um, 0.75 um, 1 um, 5 um, 10 um, 15 um, 20 um, 25 um, 30 um, 40 um, 50 um, 75 um, 100 um, 125 um, 150 um or 200 um, or any range of values therebetween. In some embodiments, the composite material comprises a release material layer with a thickness of, of about, of at least, or of at least about, 0.01 um, 0.02 um, 0.03 um, 0.04 um, 0.05 um, 0.07 um, 0.09 um, 0.1 um, 0.2 um, 0.3 um, 0.4 um, 0.5 um, 0.6 um, 0.7 um, 0.8 um, 0.9 um, 1 um, 2 um, 3 um, 4 um, 5 um, 6 um, 7 um, 8 um, 9 um, 10 um, 12 um, 15 um or 20 um, or any range of values therebetween. In some embodiments, the thickness of the composite material, release material and/or thermopolymer material may aid in compensating for flatness imperfections in the components being laminated and/or transferred. In some embodiments, the composite material is soft enough (i.e., relatively low hardness) at process temperatures to act as a stronger adhesive to pull components away from the preceding substrate. In some embodiments, a processing temperature is, is about, is at least, or is at least about, 45° C., 50° C., 60° C., 70° C., 75° C., 80° C., 90° C., 100° C., 120° C., 150° C., 175° C., 200° C., 225° C., 250° C. or 300° C., or any range of values therebetween. In some embodiments, the composite material at a processing temperature (e.g., at or at about 70° C.-200° C., 70° C., 100° C., 150° C., 200° C.) has a hardness (e.g., surface hardness) of, of about, of at most, or of at most about, 1 MPa, 1.5 MPa, 1.6 MPa, 1.7 MPa, 1.8 MPa, 1.9 MPa, 2 MPa, 2.1 MPa, 2.2 MPa, 2.2 MPa, 2.4 MPa, 2.5 MPa, 2.6 MPa, 2.7 MPa, 2.8 MPa, 2.9 MPa, 3 MPa, 3.5 MPa, 3.7 MPa, 4 MPa, 4.5 MPa, 5 MPa, 6 MPa, 6.5 MPa, 7 MPa, 8 MPa, 9 MPa, 10 MPa, 11 MPa, 12 MPa, 13 MPa, 14 MPa, 15 MPa, 18 MPa, 20 MPa, 50 MPa, 100 MPa, 200 MPa, 500 MPa, 1000 MPa or 2000 MPa, or any range of values therebetween. In some embodiments, the composite material is stiff enough (relatively high hardness) at or at about room temperature (e.g., at or at about 18° C., 19° C., 20° C., 21° C., 22° C., 23° C., 24° C. or 25° C., or any range of values therebetween) to hold components securely in place during handling steps, for example during grinding and/or laminating. In some embodiments, the composite material at room temperature (e.g., at or at about 20° C.-22° C., 20° C., 22° C.) has a hardness (e.g., surface hardness) of, of about, of at least, or of at least about, 1 MPa, 1.5 MPa, 1.6 MPa, 1.7 MPa, 1.8 MPa, 1.9 MPa, 2 MPa, 2.1 MPa, 2.2 MPa, 2.2 MPa, 2.4 MPa, 2.5 MPa, 2.6 MPa, 2.7 MPa, 2.8 MPa, 2.9 MPa, 3 MPa, 3.4 MPa, 3.5 MPa, 3.7 MPa, 4 MPa, 4.5 MPa, 5 MPa, 6 MPa, 6.5 MPa, 7 MPa, 8 MPa, 9 MPa, 10 MPa, 11 MPa, 12 MPa, 13 MPa, 14 MPa, 15 MPa, 18 MPa, 20 MPa, 50 MPa, 100 MPa, 200 MPa, 500 MPa, 1000 MPa, 2000 MPa, 3000 MPa, 4000 MPa or 5000 MPa, or any range of values therebetween.

In some embodiments, the composite material comprises, consists essentially of, consists of, or is a single layer. In some embodiments, the composite material comprises a layer including a release material and thermopolymer material. In some embodiments, the composite material comprises a plurality of layers (e.g., at or at least 2 layers (i.e., bilayer), 3 layers, 4 layers, 5 layers or 6 layers, or any range of values therebetween). In some embodiments, the composite material comprises a plurality of distinct layers (e.g., films). In some embodiments, the composite material comprises a plurality of distinct layers with graded interfaces between at least two layers. In some embodiments, the thermopolymer material layer comprises a graded interface comprising of, of about, of at least, or of at least about, 5%, 10%, 15%, 20%, 25%, 30%, 35%, 40%, 45%, 50% or 60%, or any range of values therebetween, of the thickness of the thermopolymer material layer. In some embodiments, the composite material comprises a plurality of distinct layers with distinct interfaces between at least two layers. In some embodiments, the thermopolymer material layer comprises a distinct interface comprising of, of about, of at most, or of at most about, 0.1%, 0.5%, 1%, 2%, 3%, 4%, 5% or 6%, or any range of values therebetween, of the thickness of the thermopolymer material layer. In some embodiments, the composite material comprises a release material (e.g., Terefilm®) layer and a thermopolymer material layer. In some embodiments, release material layer is adjacent to the thermopolymer material layer. In some embodiments, at least one interlayer is positioned between the release material layer and the thermopolymer material layer. In some embodiments, the composite material comprises a layer including a release material and thermopolymer material and at least one additional layer. In some embodiments, interlayers and/or additional layers may comprise a release material, a thermopolymer material, an adhesive material and combinations thereof. In some embodiments, the release material layer is adjacent to the substrate. In some embodiments, thermopolymer material layer is adjacent to the substrate. In some embodiments, the additional layer is adjacent to the substrate. In some embodiments, the release material layer is adjacent to the components. In some embodiments, thermopolymer material layer is adjacent to the components. In some embodiments, the additional layer is adjacent to the components.

In some embodiments, a substrate comprises or is disposed over a single composite material layer. In some embodiments, a substrate comprises or is disposed over a plurality of the composite material layers (e.g., at or at least 2 layers, 3 layers, 4 layers, 5 layers or 6 layers, or any range of values therebetween).

In some embodiments, the composite material is a bilayer comprising a thermopolymer material layer (e.g., wax) (e.g., 1 um to 100 um) and release material layer (e.g., Terefilm®) (e.g., 0.05 um to 10 um). In some embodiments, the bilayer comprises a distinct (i.e., “clean”, within the normal understanding of a “clean” interface by a person of ordinary skill in the art) layer (e.g., 2D) interface. In some embodiments, the bilayer comprises a graded (i.e., “fuzzy”) (e.g., the two materials are intermixed) layer interface.

In some embodiments, the composite material is a single layer of mixed thermopolymer material (e.g., wax) and release material (e.g., Terefilm®). In some embodiments, the single layer is a homogeneous or substantially homogeneous mixture of the release material and the thermopolymer material. In some embodiments, the single layer comprises a gradient of concentration from release material (e.g., Terefilm®) rich on the top to thermopolymer material rich on the bottom of the layer. In some embodiments, the single layer comprises a gradient of concentration from release material (e.g., Terefilm®) rich on the bottom to thermopolymer material rich on the top of the layer. In some embodiments, the single layer is a blend that forms domains of release material (e.g., Terefilm®) rich (e.g., pure) and domains of thermopolymer material rich (e.g., pure), which for example may be similar to the formation of block copolymer films. In some embodiments, such domains can take on an ordered or periodic structure. In some embodiments, such domains can take on a disordered structure. In some embodiments, such domains can be oriented with vertical columns of release material (e.g., Terefilm®) such that the surface appears as spots in a thermopolymer material matrix. In some embodiments, such domains can be oriented with vertical columns of thermopolymer material such that the surface appears as spots in a release material matrix.

In some embodiments, the release material (e.g., Terefilm®) polymer may be bonded (e.g., covalently bonded) to a surface (e.g., top surface, bottom surface, side surface) of a thermopolymer material (e.g., wax) layer. In some embodiments, the monomeric repeat units of the release material (e.g., Terefilm®) polymer are covalently bonded to a compound of the thermopolymer material. In some embodiments, the release material polymer is soluble in the thermopolymer material, and when intermixed is bonded thereto.

In some embodiments, the composite material comprises a bilayer including a release material layer comprising a photoacid generator, and a thermopolymer polymer layer comprising a thermally decomposable polymer with acid-sensitive linkages and a free acid (e.g., the product of the irradiated photoacid generator).

In some embodiments, the composite material layer comprises a thick layer (e.g., 5 um) comprising a release material without a photoacid generator (PAG), and a thin layer (e.g., 0.3 um) comprising a release material with a PAG. One or both of the thick and thin layers further includes the thermopolymer material. In some embodiments, the thick layer is in contact with a substrate. In some embodiments, the thin layer is in contact with a substrate. In some embodiments, the thick layer is in contact or configured to be in contact with the components. In some embodiments, the thin layer is in contact or configured to be in contact with the components. In some embodiments, the composite material layer is optically transparent for a wavelength of light that sensitizes the PAG (e.g., UV light).

### Thermopolymer Material

In some embodiments, a thermopolymer material comprises a thermopolymer compound. In some embodiments, the thermopolymer compound is a thermoplastic, a thermoset, copolymers thereof, or combinations thereof. In some embodiments, the thermopolymer compound is selected from at least one of a long chain aliphatic thermopolymer compound (e.g., a wax), an acrylic, an acrylonitrile butadiene styrene (ABS), a nylon, a polylactic acid (PLA), a polybenzimidazole, a polycarbonate, a polyether sulfone, a polyoxymethylene, a polyether ether ketone, a polyetherimide, a polyethylene, a polyphenylene oxide, a poly phenylene sulfide, a polypropylene, a poly styrene, a polyvinyl chloride, a polyvinylidene fluoride, a polytetrafluoroethylene (PTFE), an epoxy, a silicone (e.g., polydimethylsiloxane (PDMS)), a polyurethane, a phenolic, a polyester, a melamine, a urea formaldehyde, copolymers thereof, and combinations thereof. In some embodiments, the thermopolymer material comprises, consists essentially of, consists of, or is a PDMS. In some embodiments, the thermopolymer material comprises, consists essentially of, consists of, or is a wax. Examples of waxes include MWH 135 wax, MWH 080 wax, MWM 070 wax, MWS 052 wax, and combinations thereof. In some embodiments, the thermopolymer material comprises a thermally decomposable compound and/or polymer. In some embodiments, the thermally decomposable compound and/or polymer decomposes (e.g., vaporizes) at a temperature of, of about, of at least, or of at least about, 50° C., 60° C., 70° C., 80° C., 90° C., 100° C., 110° C., 120° C., 150° C., 180° C. or 200° C., or any range of values therebetween. In some embodiments, the thermally decomposable compound and/or polymer comprises acid-sensitive linkages. In some embodiments, the thermopolymer material comprises a free acid. In some embodiments, the thermopolymer material comprises a photoacid generator. In some embodiments, the thermopolymer material does not include a photoacid generator.

In some embodiments, the thermopolymer material has a melting point of, of about, of at most, or of at most about, 50° C., 52° C., 55° C., 60° C., 65° C., 70° C., 75° C., 80° C., 100° C., 110° C., 120° C., 130° C., 135° C., 140° C., 145° C., 150° C., 160° C., 165° C., 170° C., 180° C., 185° C., 190° C., 195° C., 200° C., 225° C., 250° C., 260° C., 270° C., 300° C., 350° C., 400° C., 500° C. or 600° C., or any range of values therebetween. In some embodiments, the thermopolymer material has a glass transition temperature of, of about, of at most, or of at most about, 40° C., 45° C., 50° C., 55° C., 60° C., 65° C., 70° C., 80° C., 90° C., 100° C., 105° C., 110° C., 120° C., 130° C., 140° C., 150° C., 175° C., 200° C. or 250° C., or any range of values therebetween.

In some embodiments, the thermopolymer material is compatible with a release material (e.g., Terefilm®). In some embodiments, the thermopolymer material is compatible (e.g., thermodynamically compatible) with the release material in that a layer of the release material can wet a layer of the thermopolymer material, or vice/versa. In some embodiments, the thermopolymer material is compatible with the release material in that the thermopolymer material is partially, substantially or fully miscible with the release material. For example, in some embodiments, a wax is compatible with Terefilm®. In some embodiments, the release material (e.g., release material polymer and/or formulation) is modified in order to improve compatibility with a thermopolymer material. In some embodiments, the surface of the release material layer is modified in order to improve compatibility with a thermopolymer material. In some embodiments, the surface of release material layer is modified by covalently attaching compounds with end-groups compatible (e.g., thermodynamically compatible) with the thermopolymer material character (e.g., aliphatic, siloxanes, perfluoronated, etc.) such that wetting of the thermopolymer material (e.g., aliphatic thermopolymer material, wax) layer is enhanced and/or provides improved interfacial bonding between the layers. In some embodiments, the release material layer surface is modified by a self-assembled monolayer (e.g., SAM).

### Release Material

In some embodiments, the release material comprises a polymer. In some embodiments, the polymer is a photoactive polymer. The release material may include a polymeric component that is a unit containing a tetralin or cyclohexene core and a linkage. For example, in some embodiments, the polymeric component comprises a unit of the Formula (I) and/or Formula (II).

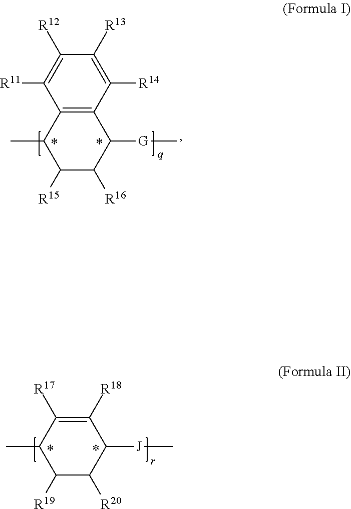

In some embodiments, each * of the Formula (I) and/or Formula (II) denotes a chiral carbon in the cyclohexene ring. In some embodiments, a chiral carbon is configured so that the cyclohexene ring is in a cis orientation. In some embodiments, a chiral carbon is configured so that the cyclohexyl ring is in a trans orientation. In some embodiments, the polymeric component has a cis:trans ratio of, of about, of at least, of at least about, of at most, or of at most about, 0:100, 5:95, 10:90, 15:85, 20:80, 25:75, 30:70, 35:65, 40:60, 45:55, 50:50, 55:45, 60:40, 65:35, 70:30, 75:25, 80:20, 85:15, 90:10, 95:5 or 100:0, or any range of values therebetween. In some embodiments, q is an integer of 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 55, 60, 65, 70, 75, 80, 85, 90, 95, 100, 120, 150, 200, 300, 400, 500, 600, 800 or 1000, or any range of values therebetween. For example, in some embodiments q is in the range of 16-50 or 16-200. In some embodiments, r is an integer of 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 55, 60, 65, 70, 75, 80, 85, 90, 95, 100, 120, 150, 200, 300, 400, 500, 600, 800 or 1000, or any range of values therebetween. For example, in some embodiments r is in the range of 16-50 or 16-200. In some embodiments, linkage G is independently —O—, —NH—,

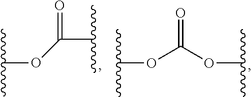

an optionally substituted

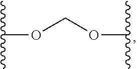 [SMILES: *OCO*]

an optionally substituted

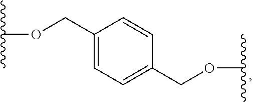 [SMILES: *OCc1ccc(CO*)cc1]

an optionally substituted

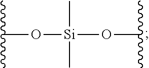 [SMILES: *O[Si](C)(C)O*]

an optionally substituted

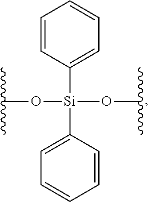 [SMILES: *O[Si](O*)(c1ccccc1)c1ccccc1]

an optionally substituted

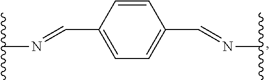 [SMILES: */N=C/c1ccc(/C=N/*)cc1]

an optionally substituted

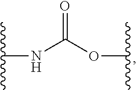 [SMILES: *NC(=O)O*]

an optionally substituted

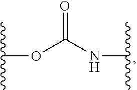 [SMILES: *NC(=O)O*]

an optionally substituted

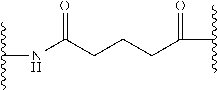 [SMILES: *NC(=O)CCCC(*)=O]

or an optionally substituted

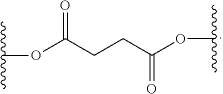 [SMILES: *OC(=O)CCC(=O)O*]

In some embodiments, linkage J is independently —O—, —NH—,

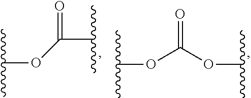

an optionally substituted

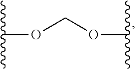 [SMILES: *OCO*]

an optionally substituted

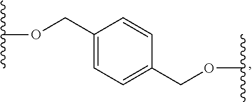 [SMILES: *OCc1ccc(CO*)cc1]

an optionally substituted

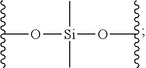 [SMILES: *O[Si](C)(C)O*]

an optionally substituted

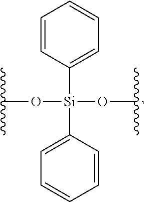 [SMILES: *O[Si](O*)(c1ccccc1)c1ccccc1]

an optionally substituted

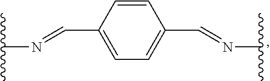 [SMILES: */N=C/c1ccc(/C=N/*)cc1]

an optionally substituted

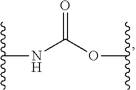 [SMILES: *NC(=O)O*]

an optionally substituted

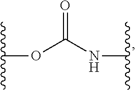 [SMILES: *NC(=O)O*]

an optionally substituted

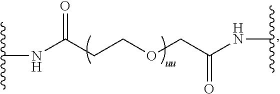

an optionally substituted

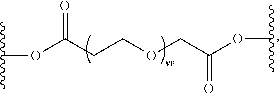

an optionally substituted

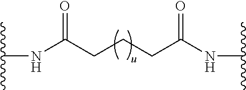

or an optionally substituted

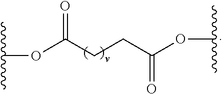

In some embodiments, each R¹¹ is independently hydrogen, halogen, C₁₋₁₀ alkyl (e.g., C₁₋₃ alkyl), C₂₋₁₀ alkenyl or C₂₋₁₀ alkynyl. In some embodiments, each R¹² is independently hydrogen, halogen, C₁₋₁₀ alkyl (e.g., C₁₋₃ alkyl), C₂₋₁₀ alkenyl or C₂₋₁₀ alkynyl. In some embodiments, each R¹³ is independently hydrogen, halogen, C₁₋₁₀ alkyl (e.g., C₁₋₃ alkyl), C₂₋₁₀ alkenyl or C₂₋₁₀ alkynyl. In some embodiments, each R¹⁴ is independently hydrogen, halogen, C₁₋₁₀ alkyl (e.g., C₁₋₃ alkyl), C₂₋₁₀ alkenyl or C₂₋₁₀ alkynyl. In some embodiments, each R¹⁵ is independently hydrogen, halogen, C₁₋₁₀ alkyl (e.g., C₁₋₃ alkyl), C₂₋₁₀ alkenyl or C₂₋₁₀ alkynyl. In some embodiments, each R¹⁶ is independently hydrogen, halogen, C₁₋₁₀ alkyl (e.g., C₁₋₃ alkyl), C₂₋₁₀ alkenyl or C₂₋₁₀ alkynyl. In some embodiments, each R¹⁷ is independently hydrogen, halogen, C₁₋₁₀ alkyl (e.g., C₁₋₃ alkyl), C₂₋₁₀ alkenyl or C₂₋₁₀ alkynyl. In some embodiments, each R¹⁸ is independently hydrogen, halogen, C₁₋₁₀ alkyl (e.g., C₁₋₃ alkyl), C₂₋₁₀ alkenyl or C₂₋₁₀ alkynyl. In some embodiments, each R¹⁹ is independently hydrogen, halogen, C₁₋₁₀ alkyl (e.g., C₁₋₃ alkyl), C₂₋₁₀ alkenyl or C₂₋₁₀ alkynyl. In some embodiments, each R²⁰ is independently hydrogen, halogen, C₁₋₁₀ alkyl (e.g., C₁₋₃ alkyl), C₂₋₁₀ alkenyl or C₂₋₁₀ alkynyl. In some embodiments, each uu is independently an integer in the range of 1 to 10. In some embodiments, each vv is independently an integer in the range of 1 to 10. In some embodiments, each u is independently an integer in the range of 1 to 10. In some embodiments, each v is independently an integer in the range of 1 to 10.

In some embodiments, polymerization of the polymer of the release material may be performed by mixing multiple monomers with a combination of hydroxy groups and nucleophilic receptors. In some embodiments, the polymerization reaction may be performed by adding a Bronsted base to catalytically deprotonate the hydroxy groups to form reactive alkoxy anions that react to form the carbonate linkage. Adding in alkoxide reactive functional group chemistries at any point during the polymerization, the polymer chain ends can be functionalized simultaneously as the polymerization reaction. In some embodiments, such reactions may include an oxa-Michael reaction between an alcohol and electron deficient alkene (e.g., an acrylate) or the nucleophilic substitution with an alkyl halide. In some embodiments, a polymer chain end or ends are functionalized with a group selected from an alkyl, an alkenyl, an alkynyl, an acrylate, a halo acrylate, a silyl acrylate, an ether, a silyl ether, a silyl, a siloxy, and combinations thereof.

Example reactions of an oxa-Michael reaction and a hydroxy/halogen SN reaction are depicted in Schemes 1 and 2 below.

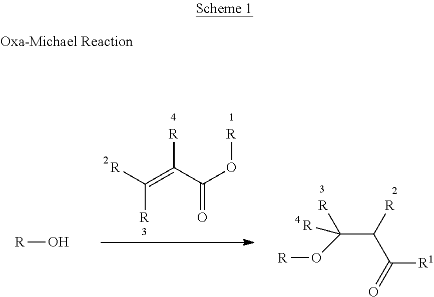

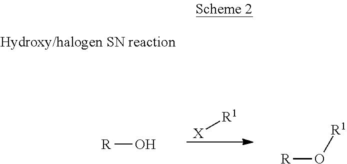

In some embodiments, in Schemes 1 and 2 the R₁ group may determine or aid in the compatibility (e.g., ability to mix into one layer and/or wet layers onto one another) of the release material polymer and the thermopolymer material. In some embodiments, due to the robust range of acrylate and alkyl halides, the R₁ group can be selected based on the thermopolymer material's chemical nature. In some embodiments, when the thermopolymer material comprises a long chain aliphatic thermopolymer compound (e.g., a wax), the acrylate and alkyl halides may be selected from

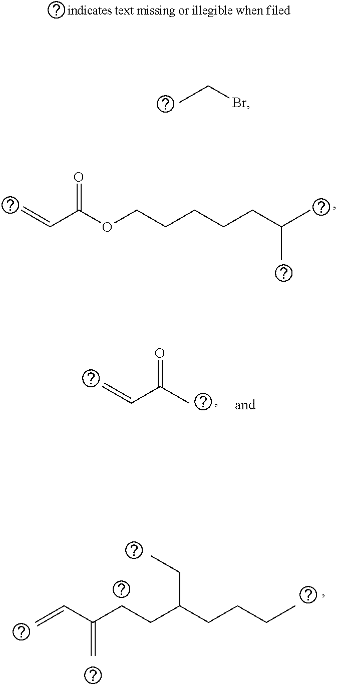

or combinations thereof.

In some embodiments, perfluoro acrylates may be utilized as a release material polymer precursor (e.g., when the thermopolymer material is fluorinated). In some embodiments, an example perfluoro acrylate may be

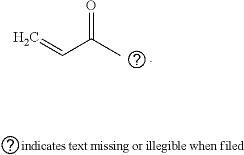

In some embodiments, silyl acrylates and/or base catalyzed silyl ether formation reactions, which place compatible silyl ether groups on the R₁ group (e.g., using a one-pot polymerization silyl ether reaction), may be utilized as a release material polymer precursor (e.g., when the underlying thermopolymer material is a siloxane in nature). In some embodiments, an example silyl acrylate may be

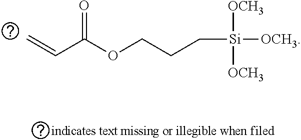

In some embodiments, an example base catalyzed silyl ether formation reaction is shown in Scheme 3 below.

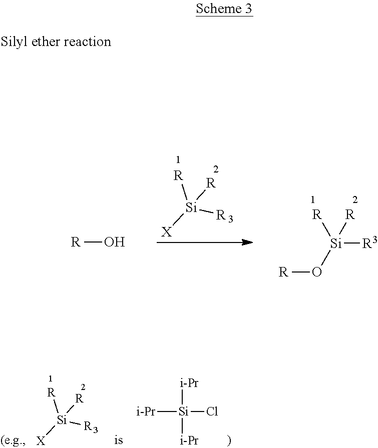

In some embodiments, the release material comprises a photoacid generator. In some embodiments, the release material does not include a photoacid generator. In some embodiments, the release material may be utilized in a composition and/or layer other than the composite material.

In some embodiments, a layer of the release material (e.g., which does not include the thermopolymer material) has a hardness (e.g., surface hardness) of, of about, of at least, or of at least about, 3 GPa, 3.5 GPa, 3.6 GPa, 3.7 GPa, 3.8 GPa, 3.9 GPa, 4 GPa, 4.1 GPa, 4.2 GPa, 4.3 GPa, 4.4 GPa, 4.5 GPa, 4.6 GPa, 4.7 GPa, 4.8 GPa, 4.9 GPa, 5 GPa, 5.5 GPa or 6 GPa, or any range of values therebetween.

### Composite Material Processes and Applications

In some embodiments, the composite material may be utilized in processes for transferring components. In some embodiments, the components may comprise silicon (Si) (e.g., for IC industry), sapphire (e.g., for LEDs), SiC, In_{w}GaₓAs_{y},N_{z}, and/or other group III-V and II-VI elements. In some embodiments, the composite material may be utilized in the field of dicing wafers comprising finished microelectronic components (e.g., chips, die, dies, dice) such as micro-LEDs, power devices, solid state batteries, radio frequency identification (RFID) devices, memory devices, and/or processors. In some embodiments, the composite material is utilized in methods (e.g., for the integrated circuit (IC) elements or for light emitting diodes (LEDs)) for dicing a wafer (e.g., SiC, In_{w}GaₓAs_{y},N_{z}, other III-V and II-VI, etc.) into individual dies.

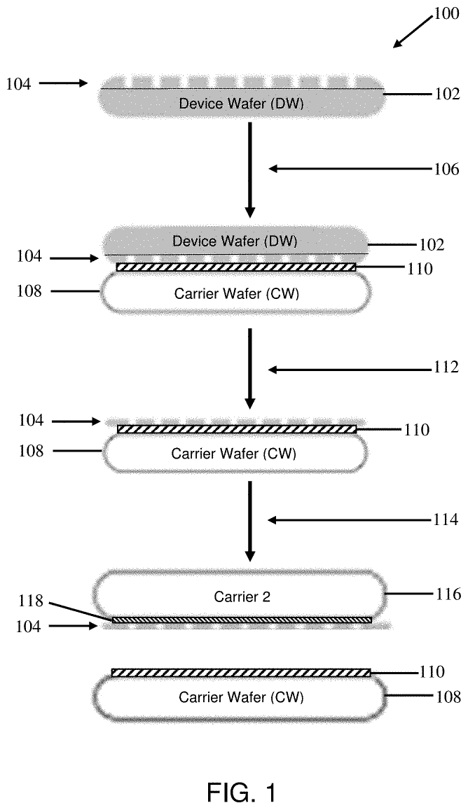

FIG. 1 depicts a process 100 of transferring components (e.g., die components) utilizing a composite material. The initial substrate 102 (e.g., device wafer; “DW”) comprises a plurality of components 104 disposed thereover. In a first step 106, the initial substrate 102 is brought into contact with a carrier substrate 108 (e.g., carrier wafer; “CW”) comprising a composite material layer 110 disposed over a surface of the carrier substrate 108, wherein the components 104 are in contact with the composite material layer 110. In a second step 112, the components 104 are held in place by the composite material layer 110 while the initial substrate 102 is separated from the components 104. In some embodiments, the remaining steps of the process 100 are not utilized and instead the resultant assembly after the second step 112 comprising the carrier substrate 108, composite material layer 110 and components 104 may be disposed over a receiving substrate, and the components 104 separated from the composite material layer 110 and transferred to the receiving substrate. In some embodiments, the separation and transfer process comprises a pick and place process, elastomer stamp, a LIFT process, an LLO process and/or exposing the composite material 110 to heat and/or light, thereby substantially or partially decomposing the composite material. As such, such a process maintains the orientation of the faces of the components 110 (e.g., active circuitry) on the receiving substrate relative to their orientations on the initial substrate 102.

Continuing with the process 100 of FIG. 1, in a third step 114, a handle 116 (Carrier 2) comprising an adhesive layer 118 is brought into contact with the components 104 such that the adhesive layer 118 contacts the components 104, and the handle 116 is lifted away from the carrier substrate 108, or vice versa, such that the components 104 are separated from the composite material 110 and the components 104 remains in contact with the adhesive layer 118, which in turn remains in contact with the handle 116. In some embodiments, the process 100 further comprises disposing the resultant assembly after the third step 114 comprising the handle 116, adhesive layer 118 and components 104 over a receiving substrate, and the components 104 separated from the adhesive layer 118 and transferred to the receiving substrate. In some embodiments, the separation and transfer process comprises a pick and place process, elastomer stamp, a LIFT process, a LLO process, and/or exposing the adhesive layer 118 to heat and/or light, thereby substantially or partially decomposing the adhesive layer 118. As such, such a process reverses (i.e., flips) the orientation of the faces of the components 110 (e.g., active circuitry) on the receiving substrate relative to their orientations on the initial substrate 102.

In some embodiments, the initial substrate is a donor plate. In some embodiments, the initial substrate comprises an initial adhesive disposed thereover. In some embodiments, the initial adhesive comprises a release material, a thermopolymer material, a composite material, another adhesive material, or combinations thereof. In some embodiments, the components may be transferred from the initial adhesive of the initial substrate by exposure to heat, light, elastomer stamp, a LIFT process, an LLO process, and/or exposure to heat and/or light. In some embodiments, the initial substrate may be a transparent (e.g., UV-transparent) substrate.

In some embodiments, the initial substrate is a wafer. In some embodiments, the wafer comprises densely packed components. In some embodiments, the wafer and/or components may comprise silicon (Si) (e.g., for IC industry), sapphire (e.g., for LEDs), SiC, In_{w}GaₓAs_{y},N_{z}, and/or other group III-V and II-VI elements. In some embodiments, the components are formed by dicing streets into the new wafer. In some embodiments, the streets (e.g., shallow streets) are diced into one side and partially through the thickness of a new wafer (e.g., using a dicing saw, plasma and/or laser) to form a component wafer comprising components separated by the streets. In some embodiments, a fabrication processes (e.g. CVD, lithography, plasma etching) is utilized to modify the components and form active components and/or form undercuts (e.g., release the tethers connecting the components to the wafer).

In some embodiments, a carrier adhesive may be utilized to separate or aid in separating the components from the initial substrate. In some embodiments, the carrier adhesive comprises a composite material, a release material, a thermopolymer material, another adhesive material, or combinations thereof. In some embodiments, the carrier adhesive comprises a composite material. In some embodiments, the adhesive does not comprise a composite material if another adhesive of the process comprises a composite material. In some embodiments, contacting the components of the initial substrate (e.g., component wafer) with the composite material temporarily bonds the components to the composite material. In some embodiments, bonding the components to a carrier adhesive includes lamination. In some embodiments, the components bonded to the composite material may be separated from the wafer. For example, in some embodiments when the component tethers are undercut such that the components are not or are not substantially contiguous with the wafer, the components bonded to the composite material may be separated from the wafer by lifting away the wafer from the components. In some embodiments, contacting the components of the component wafer with the composite material temporarily bonds the wafer to the composite material (e.g., when the when the component tethers remain). In some embodiments, the wafer bonded to the composite material is thinned (e.g., grinded) such that the wafer is removed and each of the components are separated from one another. In some embodiments, separating the wafer from the components forms multilayer composite components (e.g., GaN and related materials on top of sapphire). In some embodiments, separating the wafer from the components forms components over a modified substrate that are not easily detached from the modified substrate (e.g., for silicon integrated circuits).

In some embodiments, the components are bonded to the composite material layer and/or to the release material layer with increased adhesion relative to an adhesive that holds the components in prior steps. In some embodiments, the components are bonded to the surface of the composite material layer and/or release material layer. In some embodiments, the components are not embedded within the composite material layer and/or release material layer. In some embodiments, embedding of the components may be disadvantageous in that the depth of embedding is difficult to control, may result in non-uniform holding forces for different components and/or may result in poor placement accuracy and process control. In some embodiments, the composite material and/or thermopolymer material is compliant enough to allow a strong force to be applied during the bonding process thereby ensuring a complete, uniform bond with the components. In some embodiments, the composite material layer and/or thermopolymer material layer is thin enough to allow activating light (e.g., UV light) to penetrate through the thickness of the layer. In some embodiments, a thin layer of composite material layer and/or release material may be advantageous in order to have uniform exposure to light. In some embodiments, a thick layer of composite material layer and/or release material may be advantageous for the bonding process.

In some embodiments, the components may be transferred from the carrier adhesive (e.g., composite material) to another substrate (e.g., handle substrate, receiving substrate or device) by or with the aid of exposure to heat, light, a pick and place process, elastomer stamp, a LIFT process and/or an LLO process. In some embodiments, the composite material may be deactivated thermally and/or by exposure to light (e.g, ultraviolet (UV) light), thereby releasing or aiding in release the components adhered thereto.

The carrier adhesive (e.g., composite adhesive) may initially be disposed over a carrier substrate. In some embodiments, the carrier substrate may be flat, smooth, and/or low dig/scratch. In some embodiments, the carrier substrate may be a transparent (e.g., UV-transparent) substrate (e.g., fused silica used for lithography masks or sapphire). In some embodiments, the carrier substrate is a donor plate.

In some embodiments, a handle substrate (e.g., temporary carrier) comprising a handle adhesive may receive the components from the carrier adhesive and carrier substrate. In some embodiments, the components are contacted (e.g., bonded) to the handle adhesive. In some embodiments, the handle adhesive comprises a thermopolymer material, a release material and/or a composite material. In some embodiments, the handle adhesive does not include a release material. In some embodiments, the handle adhesive comprises a release material. In some embodiments, the components may be transferred from the handle adhesive (e.g., composite material) to another substrate (e.g., receiving substrate or device) by or with the aid of exposure to heat, light, a pick and place process, elastomer stamp, a LIFT process and/or an LLO process. In some embodiments, the handle adhesive may be deactivated thermally and/or by exposure to light (e.g., ultraviolet (UV) light), thereby releasing or aiding in release the components adhered thereto. In some embodiments, the handle substrate and the handle adhesive together are a dicing tape.

In some embodiments, the handle substrate is or is substantially transparent (e.g., to UV light). In some embodiments, the handle substrate is not or is not substantially transparent.

In some embodiments, the receiving substrate may receive the components from the carrier substrate and/or the handle substrate. In some embodiments, the receiving substrate is a donor plate, and/or a package substrate (e.g., semiconductor, microLED, printed circuit board (PCB)) that may create or be used to create integrated circuits or placed in a backplane (e.g., miniLED, microLED). In some embodiments, the receiving substrate is a package substrate (e.g., semiconductor, microLED, printed circuit board (PCB)) or a backplane (e.g., miniLED, microLED).

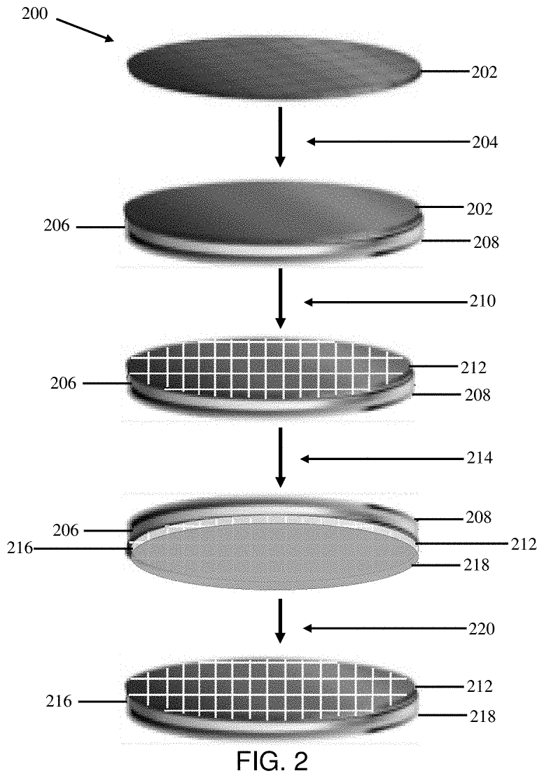

FIG. 2 depicts a process 200 of dicing a wafer into individual die components by grinding and placing them onto a stretchable film utilizing a composite material, according to some embodiments. In a first step 204, the components of the component wafer 202 are contacted by a composite material layer 206 disposed over a carrier substrate 208, wherein the dicing streets facing the composite material layer 206. In a second step 210, the component wafer 202 is thinned (e.g., mechanically grinded) from the back side followed by chemical-mechanical polishing (CMP) until the removal meets the dicing streets and the components 212 remain disposed over the composite material 206. In some embodiments, the remaining steps of the process 200 are not utilized and instead the resultant assembly of the second step 210 comprising the carrier substrate 208, composite material 206 and components 212 may be disposed over a receiving substrate and the composite material 206 may be decomposed and/or deactivated thermally and/or by exposure to light (e.g., ultraviolet (UV) light) thereby releasing the components adhered thereto thereby transferring the components 212 to the receiving substrate. In some embodiments, a LIFT process (e.g., exposure to heat and light) is initiated on the composite material 206 such that the release material decomposes. As such, such a process maintains the orientation of the faces of the components (e.g., active circuitry) on the receiving substrate relative to their orientations on the component wafer 202.

Continuing with the process 200 of FIG. 2, in a third step 214, the carrier substrate 208, composite material 206 and components 212 are flipped (i.e., rotated 180°) and the components 212 are contacted by a carrier tape comprising an adhesive 216 disposed over a stretchable film 218 (i.e., dicing tape) such that the adhesive 216 is in contact with the components 216. In some embodiments, the composite material 206 may be deactivated thermally and/or by exposure to light (e.g., ultraviolet (UV) light) (e.g., a LIFT process) thereby releasing the components adhered thereto. In a fourth step 220, the components 212 are separated from the composite material 206, and thereby the carrier substrate 208, and form an assembly comprising the components 212 disposed over the adhesive 216 which is disposed over the stretchable film 218. In some embodiments, the stretchable film 218 can be uniformly or non-uniformly stretched to increase the width of the streets in one or more directions such that the components are less densely packed. In some embodiments, the stretched stretchable film 218 is bonded to a metal ring. In some embodiments, the components 212 may be released from the adhesive 216 and thereby placed onto a receiving substrate. As such, such a process reverses (i.e., flips) the orientation of the faces of the components (e.g., active circuitry) on the receiving substrate relative to their orientations on the component wafer 202.

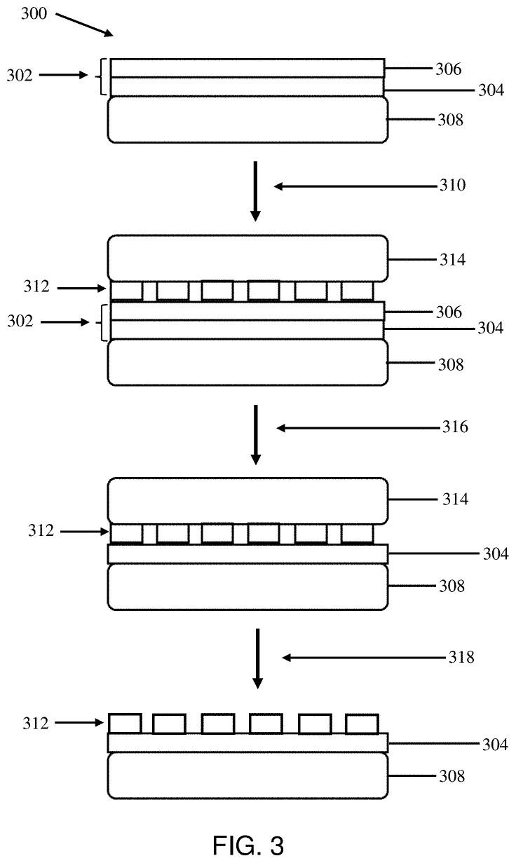

FIG. 3 depicts a process 300 of transferring components from a source substrate to a carrier substrate by utilizing a bilayer composite material. A carrier assembly comprising a composite material layer 302 disposed over a carrier substrate 308 is initially provided. The composite material layer 302 is a bilayer including a release material layer 304 in contact with the carrier substrate 308, and a thermopolymer material layer 306 in contact with the release material layer 304. In a first step 310, components 312 disposed over a source substrate 314 are brought into contact with the thermopolymer material layer 306. In some embodiments, the components 312 can be pushed into the thermopolymer material layer 306 without concern for the specific depth of penetration. In some embodiments, the thermopolymer material layer 306 is softened. In some embodiments, softening is due to increased temperature and/or solvent exposure of the thermopolymer material layer 306. In a second step 316, the thermopolymer material layer 306 is decomposed, thereby causing the components 312 to contact the surface of the release material layer 304. In a third step 318, the carrier substrate 308 is separated from the components 312, leaving a carrier component assembly comprising components 312 disposed over a release material layer 304 which is disposed over a carrier substrate 308.

In some embodiments of the process 300 of FIG. 3, the release material layer comprises a photoacid generator, and the thermopolymer material layer comprises a thermally decomposable polymer and a free acid. In some embodiments, decomposing the thermopolymer material layer comprises heating (e.g., baking) the thermopolymer material layer at a low temperature (e.g., 80° C.) to vaporize the thermopolymer material layer, while the underlying release material layer remains. As the thermopolymer material layer vaporizes, the components may settle onto the underlying release material layer and thereby form intimate van der Waals bonds. Thus, the bonding strength of components to the release material layer may be high (e.g., maximized) without using excess temperature or pressure and/or without penetration of the components into the release material layer.

While certain embodiments have been described, these embodiments have been presented by way of example only, and are not intended to limit the scope of the disclosure. Indeed, the novel methods and systems described herein may be embodied in a variety of other forms. Furthermore, various omissions, substitutions and changes in the systems and methods described herein may be made without departing from the spirit of the disclosure. The accompanying claims and their equivalents are intended to cover such forms or modifications as would fall within the scope and spirit of the disclosure.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, and/or others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products. For example, any of the components for an energy storage system described herein can be provided separately, or integrated together (e.g., packaged together, or attached together) to form an energy storage system.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount, depending on the desired function or desired result.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

The headings provided herein, if any, are for convenience only and do not necessarily affect the scope or meaning of the devices and methods disclosed herein.

What is claimed is:

1. A composite material, comprising:
a release material comprising a photoactive polymer; and
a thermopolymer material comprising a thermopolymer compound.

2. The composite material of claim 1, wherein the thermopolymer compound is selected from the group consisting of a thermoplastic, a thermoset, a copolymer thereof, and a combination thereof.

3. The composite material of claim 1, wherein the thermopolymer material has a glass transition temperature of about 50° C.-150° C.

4. The composite material of claim 1, wherein the release material further comprises a photoacid generator (PAG).

5. The composite material of claim 1, wherein the composite material is a film.

6. The composite material of claim 5, wherein the film comprises a thickness of about 1 um-100 um.

7. The composite material of claim 5, wherein the film is a single layer.

8. The composite material of claim 5, wherein the film comprises a plurality of layers.

9. The composite material of claim 8, wherein a first layer comprises the release material and a second layer comprises the thermopolymer material.

10. A carrier assembly, comprising:
a carrier substrate; and
the composite material of claim 1 disposed over the carrier substrate.

11. The carrier assembly of claim 10, further comprising a component disposed over and in contact with the composite material.

12. A wafer assembly, comprising:
a wafer substrate;
a plurality of components disposed over the wafer substrate; and
the composite material of claim 1 disposed over and in contact with the plurality of components.

13. The wafer assembly of claim 12, further comprising a carrier substrate disposed over the composite material.

14. A process, comprising:
contacting a composite material layer disposed over a carrier substrate to a plurality of components disposed over an initial substrate, wherein the composite material layer comprises a release material and a thermopolymer material; and
removing the initial substrate to result in a plurality of components adhered to the composite material layer.

15. The process of claim 14, wherein the initial substrate is a donor plate.

16. The process of claim 15, wherein the donor plate comprises an adhesive layer positioned between the donor plate and the plurality of components.

17. The process of claim 14, wherein the initial substrate is a wafer.

18. The process of claim 17, wherein the removal of the wafer comprises thinning the wafer.

19. The process of claim 14, further comprising degrading the composite material layer.

20. The process of claim 19, wherein degrading the composite material releases the plurality of components and transfers the plurality of components to a receiving substrate.

21. The process of claim 20, wherein the receiving substrate is selected from the group consisting of a donor plate, a package substrate, a backplane, and combinations thereof.

22. The process of claim 19, wherein the composite material layer comprises a first layer comprising the release material and a second layer comprising the thermopolymer material, and wherein degrading the composite material degrades the second layer thereby bonding the plurality of components to the first layer.

23. The process of claim 19, wherein degrading the composite material comprises exposing the composite material to a process selected from the group consisting of irradiating, heating, a LIFT process, an LLO process, and combinations thereof.

24. The process of claim 14, further comprising contacting the plurality of components adhered to the composite material layer to a handle adhesive disposed over a handle substrate, and transferring the plurality of components away from the composite material to the handle adhesive.
